(19) United States
(12) Patent Application Publication
(10) Pub. No.: US 2026/0262264 A1
(43) Pub. Date: Sep. 3, 2026

(54) SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventor: Ryota SUZUKI, Nisshin-shi (JP)

(21) Appl. No.: 19/542,742

(22) Filed: Feb. 18, 2026

(30) Foreign Application Priority Data
Feb. 28, 2025 (JP) 2025-031570

(51) Int. Cl. H10D 62/10; H10D 30/66

(52) U.S. Cl. CPC H10D 62/105; H10D 30/668

(57) ABSTRACT

A semiconductor device includes a lower electrode, a super junction layer, electric field relaxation layers, a current spreading layer, a body region, a connection region having an upper part in contact with the body region and a lower part in contact with the electric field relaxation layers, a source region, gate portions, and an upper electrode. In a vertical top view, the electric field relaxation layers partially overlap with the gate portions. The gate portions are disposed so that a plurality of first opening regions are defined between adjacent gate portions spaced apart at a first inter-gate distance and a plurality of second opening regions are defined between adjacent gate portions spaced apart at a second inter-gate distance smaller than the first inter-gate distance. The connection region is disposed in at least one of the first opening regions, but is not disposed in the second opening regions.

### CROSS REFERENCE TO RELATED APPLICATION

The present application claims the benefit of priority from Japanese Patent Application No. 2025-031570 filed on Feb. 28, 2025. The entire disclosures of the above application are incorporated herein by reference.

### TECHNICAL FIELD

The present disclosure relates to a semiconductor device.

### BACKGROUND

There is a vertical-type power semiconductor device having a trench gate. The semiconductor device has a stripe-shaped p-type base region extending in parallel with a trench at a lower part of the trench gate, and connection regions of a p-type disposed at a lower part of a p-type body region between adjacent trench gates. The connection regions are disposed at regular intervals in the longitudinal direction of the trench. The p-type base region is electrically connected to an upper electrode by the connection regions. This configuration may stabilize the potential of the p-type base region and relax an electric field of a gate insulating film at the lower part of the trench gate.

### SUMMARY

According to an aspect of the present disclosure, a semiconductor device includes: a lower electrode; a semiconductor substrate disposed in contact with an upper surface of the lower electrode and including a source region and a body region; a plurality of gate portions each disposed to face the body region and the source region; and an upper electrode disposed above a substrate surface of the semiconductor substrate and electrically connected to the source region and the body region. The semiconductor substrate may include: a super junction layer disposed above the lower electrode and having a first column of a first conductivity type extending in a first direction and a second column of a second conductivity type extending in the first direction, the first column and the second column being alternately and repeatedly arranged along a second direction intersecting the first direction; a plurality of electric field relaxation layers of the second conductivity type disposed in contact with an upper surface of the super junction layer, extending in a third direction intersecting the first direction, and disposed so that a semiconductor layer of the first conductivity type is interposed between adjacent electric field relaxation layers; a current spreading layer of the first conductivity type disposed in contact with upper surfaces of the plurality of electric field relaxation layers; the body region of the second conductivity type disposed in contact with an upper surface of the current spreading layer; a connection region of the second conductivity type having an upper part in contact with the body region and a lower part in contact with at least one of the plurality of electric field relaxation layers, and electrically connecting the body region and the at least one of the plurality of electric field relaxation layers; and the source region of the first conductivity type disposed in an upper part of the body region and exposed at the substrate surface of the semiconductor substrate. The plurality of electric field relaxation layers have a second conductivity type impurity concentration higher than a second conductivity type impurity concentration of the second column. In a vertical top view when viewed perpendicular to the substrate surface of the semiconductor substrate, the plurality of electric field relaxation layers partially overlap with the plurality of gate portions. The plurality of gate portions are disposed so that a plurality of first opening regions and a plurality of second opening regions are defined between adjacent gate portions in the vertical top view, each of the plurality of first opening regions is defined between adjacent gate portions spaced apart at a first inter-gate distance, and each of the plurality of second opening regions is defined between adjacent gate portions spaced apart at a second inter-gate distance smaller than the first inter-gate distance. The connection region is disposed in at least one of the plurality of first opening regions and is not disposed in the plurality of second opening regions.

### BRIEF DESCRIPTION OF DRAWINGS

Objects, features and advantages of the present disclosure will become more apparent from the following detailed description made with reference to the accompanying drawings, in which like parts are designated by like reference numbers and in which:

FIG. 1 is a cross-sectional perspective view of a semiconductor device according to a first embodiment;

FIG. 2 is a cross-sectional perspective view of the semiconductor device according to the first embodiment;

FIG. 3 is a cross-sectional perspective view of the semiconductor device according to the first embodiment;

FIG. 4 is a cross-sectional view taken along a line IV-IV in FIG. 1;

FIG. 5 is a diagram showing an arrangement ratio of first and second inter-gate distances;

FIG. 6 is a cross-sectional view of a main part of a semiconductor device according to a second embodiment;

FIG. 7 is a cross-sectional view of the main part of the semiconductor device according to the second embodiment;

FIG. 8 is a plan view of the semiconductor device according to the second embodiment; and

FIG. 9 is a plan view showing a modification of the semiconductor device according to the second embodiment.

### DETAILED DESCRIPTION

In a semiconductor device, in order to improve breakdown voltage by completely depleting a stripe-shaped p-type base region, it is necessary to further expand a depletion layer spreading from an interface of the p-type base region. If the p-type impurity concentration of the p-type base region is lowered in order to expand the depletion layer, the electrical resistance of the p-type base region increases. Thus, when an avalanche current is generated, a voltage drop generated in the p-type base region by a hole current is likely to increase. As a result, the potential of the p-type base region is not stabilized, and the electric field of the gate insulating film is likely to be increased. There is a possibility that the gate insulating film will deteriorate.

According to an aspect of the present disclosure, a semiconductor device includes: a lower electrode; a semiconductor substrate disposed in contact with an upper surface of the lower electrode and including a source region and a body region; a plurality of gate portions each disposed to face the body region and the source region; and an upper electrode disposed above a substrate surface of the semiconductor substrate and electrically connected to the source region and the body region. The semiconductor substrate includes: a super junction layer disposed above the lower electrode and having a first column of a first conductivity type extending in a first direction and a second column of a second conductivity type extending in the first direction, the first column and the second column being alternately and repeatedly arranged along a second direction intersecting the first direction; a plurality of electric field relaxation layers of the second conductivity type disposed in contact with an upper surface of the super junction layer, extending in a third direction intersecting the first direction, and disposed so that a semiconductor layer of the first conductivity type is interposed between adjacent electric field relaxation layers; a current spreading layer of the first conductivity type disposed in contact with upper surfaces of the plurality of electric field relaxation layers; the body region of the second conductivity type disposed in contact with an upper surface of the current spreading layer; a connection region of the second conductivity type having an upper part in contact with the body region and a lower part in contact with at least one of the plurality of electric field relaxation layers, and electrically connecting the body region and the at least one of the plurality of electric field relaxation layers; and the source region of the first conductivity type disposed in an upper part of the body region and exposed at the substrate surface of the semiconductor substrate. The plurality of electric field relaxation layers have a second conductivity type impurity concentration higher than a second conductivity type impurity concentration of the second column. In a vertical top view when viewed perpendicular to the substrate surface of the semiconductor substrate, the plurality of electric field relaxation layers partially overlap with the plurality of gate portions. The plurality of gate portions are disposed so that a plurality of first opening regions and a plurality of second opening regions are defined between adjacent gate portions in the vertical top view, in which each of the plurality of first opening regions is defined between adjacent gate portions spaced apart at a first inter-gate distance, and each of the plurality of second opening regions is defined between adjacent gate portions spaced apart at a second inter-gate distance smaller than the first inter-gate distance. The connection region is disposed in at least one of the plurality of first opening regions and is not disposed in the plurality of second opening regions.

In this specification, one of the first conductivity type and the second conductivity type refers to an n-type, and the other refers to a p-type.

In the semiconductor device described above, the electric field relaxation layer is connected to the upper electrode via the connection region and the body region. Therefore, the electric field relaxation layer has a potential substantially equivalent to that of the upper electrode. When a hole current is generated during a high-speed switching operation or an avalanche operation, the hole current flows into the electric field relaxation layer and flows to the upper electrode via the connection region. In the configuration described above, the first opening region is wider than the second opening region, and the connection region is selectively disposed in the first opening region. Therefore, compared to a configuration in which the connection region is disposed also in the second opening region, the area of the connection region can be increased, so that the electrical resistance of the connection region can be reduced. This makes it possible to suppress a voltage drop generated in the electric field relaxation layer by the hole current, thereby making it possible to stabilize the potential of the electric field relaxation layer.

Further, in the configuration described above, the super junction layer is provided. The second conductivity type impurity concentration of the electric field relaxation layer is higher than the second conductivity type impurity concentration of the second column of the super junction layer. Since the electrical resistance of the electric field relaxation layer can be reduced by increasing the concentration of the electric field relaxation layer, it is possible to suppress the voltage drop generated in the electric field relaxation layer. Further, since the impurity concentration of the second column is low, a depletion layer can be spread throughout the super junction layer, so that the breakdown voltage can be improved. It becomes possible to achieve both improvement in reliability and improvement in breakdown voltage of the semiconductor device.

Hereinafter, embodiments of the present disclosure will be described with reference to the drawings.

### First Embodiment

### Schematic Configuration of Semiconductor Device 1

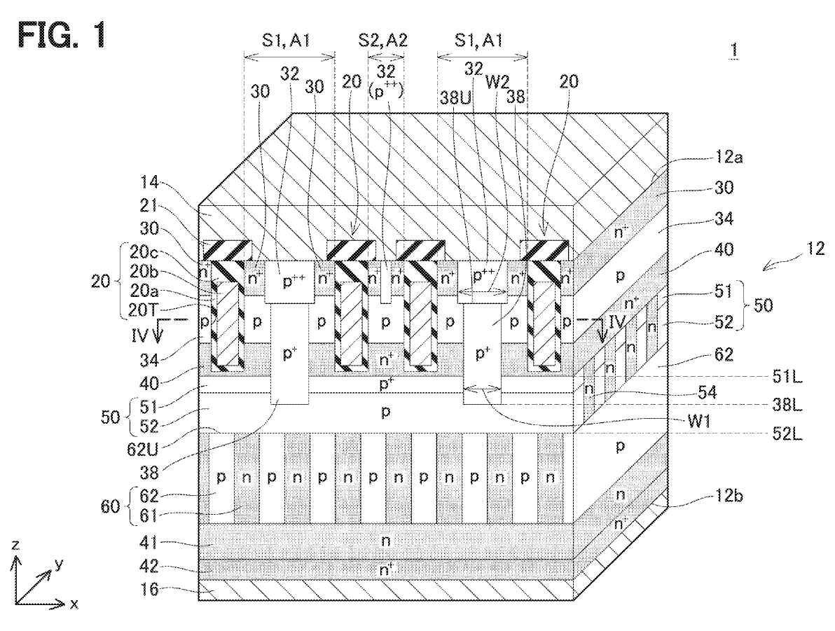

FIGS. 1 to 3 show cross-sectional perspective views of a semiconductor device 1. The semiconductor device 1 is a power semiconductor element called a metal oxide semiconductor field effect transistor (MOSFET). The semiconductor device 1 is a vertical device including trench-type gate portions 20. In FIGS. 1 to 3, a thickness direction of a semiconductor substrate 12 is referred to as a z direction, one direction in a plane perpendicular to the z direction is referred to as an x direction, and a direction orthogonal to the x direction in the plane is referred to as a y direction. For ease of viewing, n-type regions are shown in gray, and p-type regions are shown in white, i.e. without hatching. Further, electrodes are shown with thin hatching, and insulating layers are shown with thick hatching. Note that regarding parts existing in plurality, a reference numeral may be attached to a representative one of them for description. The same applies to other drawings.

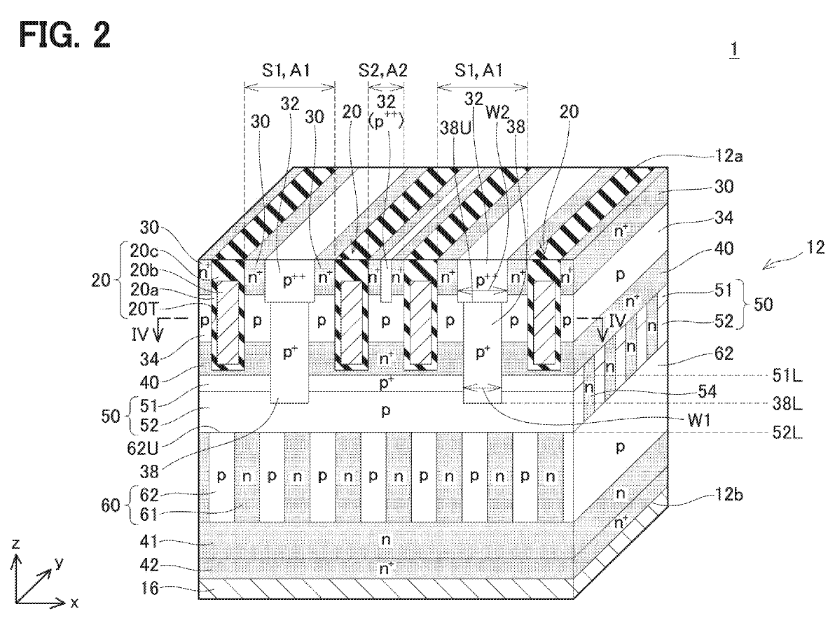

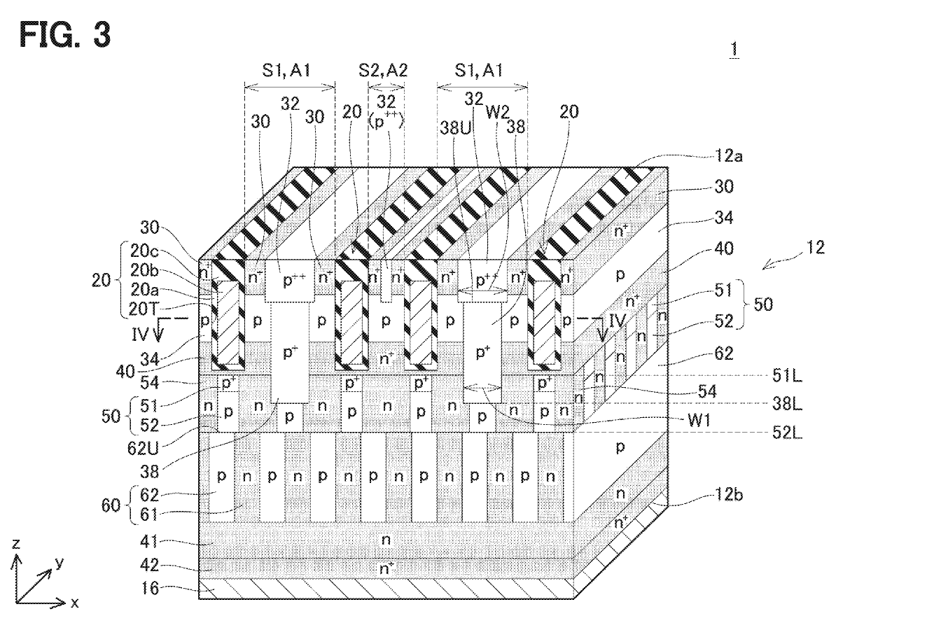

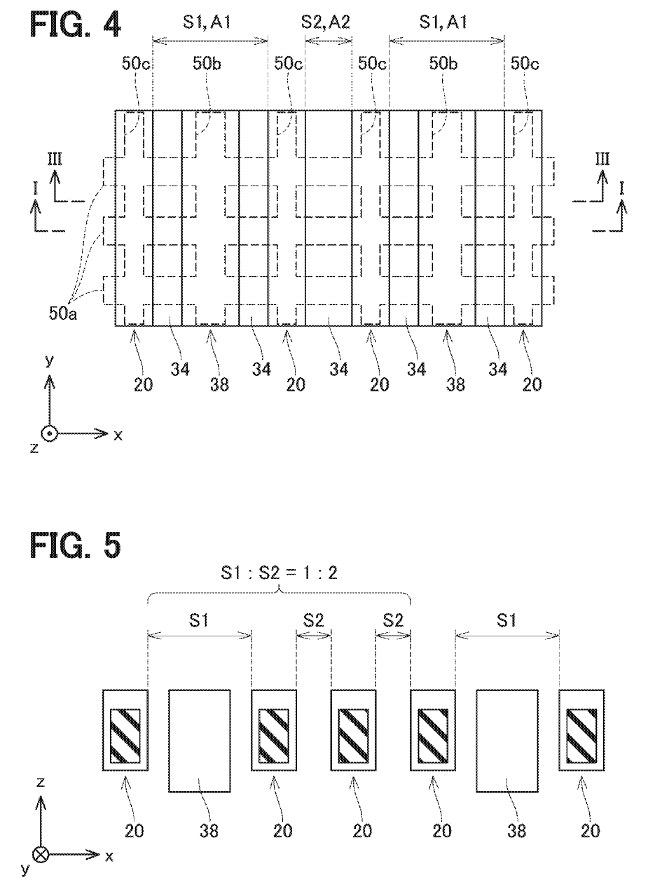

FIGS. 1 and 2 are cross-sectional views taken along a line I-I in FIG. 4 described later. FIG. 3 is a cross-sectional view taken along a line III-III in FIG. 4. That is, FIGS. 1 and 2 are cross-sectional views taken along a position passing through an electric field relaxation layer 50, and FIG. 3 is a cross-sectional view taken along a position passing through an n-type layer 54. FIG. 2 is a cross-sectional view in which the illustration of a source electrode 14 is omitted from FIG. 1.

In the first embodiment, a configuration will be described in which a plurality of gate portions 20 extend in the y direction and are arranged in a stripe shape when viewed from the +z direction perpendicular to a substrate surface 12a, that is, in a vertical top view. The semiconductor device 1 has the semiconductor substrate 12, the source electrode 14, and a drain electrode 16. The semiconductor substrate 12 is made of silicon carbide (SiC). However, the semiconductor substrate 12 may be made of other semiconductor materials such as silicon (Si) and gallium nitride (GaN). As shown in FIG. 1, the source electrode 14 covers the substrate surface 12a of the semiconductor substrate 12. Further, as shown in FIGS. 1 to 3, the drain electrode 16 covers a lower surface 12b of the semiconductor substrate 12. The source electrode 14 may correspond to an upper electrode and the drain electrode 16 may correspond to a lower electrode. In this specification the vertical top view corresponds to a view when a component is viewed in a direction perpendicular to the substrate surface 12a or a view when a component is projected in the direction perpendicular to the substrate surface 12a.

The semiconductor substrate 12 mainly includes a drain layer 42, a drift layer 41, a super junction layer (SJ layer) 60, the electric field relaxation layer 50, the n-type layer 54, a current spreading layer 40, a body region 34, a contact region 32, a source region 30, a connection region 38, and the gate portion 20.

The drain layer 42 is an n-type region. The drain layer 42 is in ohmic contact with the drain electrode 16 at the lower surface 12b of the semiconductor substrate 12. The drift layer 41 is disposed in contact with an upper surface of the drain layer 42. In the present embodiment, the drift layer 41 is an n-type region having an n-type impurity concentration lower than that of the drain layer 42.

The SJ layer 60 is disposed in contact with an upper surface of the drift layer 41. The SJ layer 60 includes a plurality of n-type first columns 61 extending in the y direction and a plurality of p-type second columns 62 extending in the y direction. The plurality of first columns 61 and the plurality of second columns 62 are alternately and repeatedly disposed along the x direction.

The plurality of electric field relaxation layers 50 are disposed in contact with an upper surface of the SJ layer 60. Each of the plurality of electric field relaxation layers 50 extends in the x direction. That is, the extending direction (x direction) of the electric field relaxation layer 50 intersects the extending direction (y direction) of the second column 62. The n-type layer 54, which is an n-type semiconductor layer, is disposed between the adjacent electric field relaxation layers 50.

Each of the plurality of electric field relaxation layers 50 includes a first electric field relaxation layer 51 and a second electric field relaxation layer 52. The second electric field relaxation layer 52 is located below the first electric field relaxation layer 51. A p-type impurity concentration of the second electric field relaxation layer 52 is higher than a p-type impurity concentration of the second column 62. Further, a p-type impurity concentration of the first electric field relaxation layer 51 is higher than the p-type impurity concentration of the second electric field relaxation layer 52. A specific planar structure of the electric field relaxation layer 50 will be described later.

The current spreading layer 40 is disposed in contact with upper surfaces of the electric field relaxation layers 50 and the n-type layers 54. The current spreading layer 40 is an n-type region having an n-type impurity concentration lower than that of the source region 30. The body region 34 is in contact with an upper surface of the current spreading layer 40. The body region 34 is a p-type region.

The plurality of source regions 30 are disposed at an upper part of the body region 34 and are exposed on the substrate surface 12a. The plurality of source regions 30 are separated from the current spreading layer 40 by the body region 34. Each source region 30 is an n-type region having a high impurity concentration. Each source region 30 is in contact with a gate insulating film 20a at an upper end of a side surface of the gate portion 20. Each source region 30 extends linearly along the y direction. Each source region 30 is in ohmic contact with the source electrode 14.

The plurality of gate portions 20 are disposed at the substrate surface 12a of the semiconductor substrate 12. The gate portion 20 includes a trench 20T, the gate insulating film 20a, a gate electrode 20b, and an upper insulating film 20c. The trench 20T extends from the substrate surface 12a toward a deep position. The trench 20T penetrates the source region 30 and the body region 34 and reaches the current spreading layer 40. The gate insulating film 20a covers an inner surface of the trench 20T. The gate electrode 20b is disposed in a position surrounded by the gate insulating film 20a. The gate electrode 20b is insulated from the semiconductor substrate 12 by the gate insulating film 20a. The gate electrode 20b faces the body region 34 and the source region 30 via the gate insulating film 20a. The gate electrode 20b faces the body region 34, which separates the current spreading layer 40 and the source region 30, via the gate insulating film 20a.

An upper surface of the gate electrode 20b is covered with the upper insulating film 20c. Further, an upper surface of the upper insulating film 20c is covered with an interlayer insulating film 21. The gate electrode 20b is insulated from the source electrode 14 by the upper insulating film 20c and the interlayer insulating film 21. Each gate electrode 20b is connected to a gate pad provided at a position not shown. The potential of each gate electrode 20b is controlled by the gate pad.

In the vertical top view, each of the plurality of gate portions 20 continuously extends in the y direction and is disposed with an interval in the x direction. There are two types of distances between the gate portions 20 adjacent to each other in the x direction: a first inter-gate distance S1 and a second inter-gate distance S2. The second inter-gate distance S2 is smaller than the first inter-gate distance S1. The regularity of the arrangement of the first inter-gate distance S1 and the second inter-gate distance S2 in the x direction may differ. In the present embodiment, the first inter-gate distance S1 and the second inter-gate distance S2 are arranged alternately one by one. That is, the arrangement ratio of the first inter-gate distance S1 and the second inter-gate distance S2 is “1:1”.

Hereinafter, a region sandwiched by two gate portions 20 disposed with the first inter-gate distance S1 therebetween is defined as a first opening region A1. Also, a region sandwiched by two gate portions 20 disposed with the second inter-gate distance S2 therebetween is defined as a second opening region A2. The first opening region A1 and the second opening region A2 continuously extend in the y direction.

The plurality of contact regions 32 are disposed in the first opening regions A1 and the second opening regions A2. Each contact region 32 is a p-type region having a high impurity concentration. The source regions 30 are disposed adjacent to side surfaces of the contact region 32 in the ± x direction. That is, the source regions 30 are disposed on opposite sides of the contact region 32 in the x direction. Each contact region 32 extends linearly along the y direction and is exposed at the substrate surface 12a. Each contact region 32 is in ohmic contact with the source electrode 14.

The connection regions 38 are disposed in the regions corresponding to the plurality of first opening regions A1, but are not disposed in the regions corresponding to the plurality of second opening regions A2. The connection region 38 is a p-type region. A p-type impurity concentration of the connection region 38 is lower than the p-type impurity concentration of the contact region 32. Further, the p-type impurity concentration of the connection region 38 is higher than p-type impurity concentrations of the body region 34 and the second electric field relaxation layer 52.

In the vertical top view, the connection region 38 is disposed within a region corresponding to the contact region 32. The connection region 38 extends linearly along the y direction. A width W1 of the connection region 38 in the x direction is smaller than a width W2 of the contact region 32 in the x direction. That is, the entirety of the connection region 38 overlaps with the contact region 32. The body region 34 is adjacent to side surfaces of the connection region 38 in the ±x direction. That is, the connection region 38 and the gate electrode 20b are disposed apart from each other.

An upper end 38U of the connection region 38 is in contact with a lower end of the contact region 32. Further, an upper part of the connection region 38 is in contact with the body region 34, and a lower part of the connection region 38 is in contact with the electric field relaxation layers 50. That is, the connection region 38 electrically connects the contact region 32 and the body region 34 to the electric field relaxation layers 50. A lower end 38L of the connection region 38 is located below a lower end 51L of the first electric field relaxation layer 51. Further, a lower end 38L of the connection region 38 is located above a lower end 52L of the second electric field relaxation layer 52. That is, an upper end 62U of the second column 62 is separated from the lower end 51L of the first electric field relaxation layer 51 and the lower end 38L of the connection region 38.

### (Planar Structure of Electric Field Relaxation Layer 50)

FIG. 4 shows a cross-sectional view taken along line IV-IV in FIG. 1. FIG. 4 is a cross-sectional view taken along a plane passing through the connection regions 38 and the gate portions 20. That is, FIG. 4 is a vertical top view of the electric field relaxation layer 50 when viewed from vertically above. In FIG. 4, the electric field relaxation layer 50 is shown by dotted lines. For ease of understanding, illustration of the gate insulating film 20a and the gate electrode 20b is omitted.

The electric field relaxation layer 50 includes a plurality of base portions 50a, a plurality of first portions 50b, and a plurality of second portions 50c. Each of the plurality of base portions 50a continuously extends in the x direction and is disposed with an interval in the y direction. Each base portion 50a crosses the plurality of gate portions 20. That is, the base portion 50a partially overlaps with the gate portions 20 in the vertical top view. Further, the plurality of base portions 50a cross the connection region 38. Thus, the connection region 38 is electrically connected to the plurality of base portions 50a along the y direction.

Each first portion 50b continuously extends in the y direction and overlaps with the connection region 38. Each second portion 50c continuously extends in the y direction and overlaps with the gate portion 20.

### Operation of Semiconductor Device 1

The semiconductor device 1 is used in a state where a potential higher than that of the source electrode 14 is applied to the drain electrode 16. When a potential equal to or higher than a gate threshold is applied to the gate electrode 20b, a channel is formed in a range adjacent to the gate insulating film 20a in the body region 34. The source region 30 is connected to the current spreading layer 40 by the channel. Thus, electrons flow from the source electrode 14 into the current spreading layer 40 via the source region 30 and the channel. The electrons flowing into the current spreading layer 40 flow to the drain electrode 16 via the n-type layer 54, the first column 61, the drift layer 41, and the drain layer 42.

When the potential of the gate electrode 20b is lowered to a potential less than the gate threshold, the channel disappears, and the semiconductor device 1 turns off. The SJ layer 60 is configured such that, in the repeating direction (x direction), a density of positive fixed charges when the plurality of first columns 61 are depleted and a density of negative fixed charges when the plurality of second columns 62 are depleted are balanced. Therefore, the plurality of first columns 61 and the plurality of second columns 62 are substantially completely depleted, and a wide range of the SJ layer 60 is depleted. Further, the electric field distribution of the SJ layer 60 is leveled in the depth direction. For this reason, the SJ layer 60 can bear a large potential difference, so that the semiconductor device 1 can have a characteristic of high breakdown voltage.

Further, when the semiconductor device 1 turns off, the potentials of the n-type layer 54 and the current spreading layer 40 rise. Since the electric field relaxation layer 50 is connected to the source electrode 14 via the connection region 38 and the contact region 32, the electric field relaxation layer 50 has substantially the same potential as the source electrode 14. For this reason, when the potentials of the n-type layer 54 and the current spreading layer 40 rise, a reverse voltage is applied to a pn junction interface between the n-type layer 54 and the electric field relaxation layer 50 and a pn junction interface between the current spreading layer 40 and the electric field relaxation layer 50. Therefore, a depletion layer spreads from the electric field relaxation layer 50 to the n-type layer 54 and the current spreading layer 40. Due to the spread of this depletion layer, the electric field generated at the lower end of the gate portion 20 can be suppressed. In particular, since the electric field relaxation layer 50 has substantially the same potential as the source electrode 14, the electric field generated at the lower end of the gate portion 20 can be effectively suppressed.

### Effects

When the semiconductor device 1 turns off, the current flowing through the semiconductor device 1 decreases rapidly, so a high surge voltage is applied to the semiconductor device 1. This may generate a high electric field and cause an avalanche current. Therefore, the semiconductor device 1 of the present embodiment has a structure in which the electric field relaxation layer 50 is connected to the source electrode 14 via the connection region 38 and the contact region 32. The electric field relaxation layer 50 has a potential substantially equivalent to that of the source electrode 14. Therefore, when an avalanche current is generated, the avalanche current flows into the electric field relaxation layer 50 and flows to the source electrode 14 via the connection region 38. In the semiconductor device 1 of the present embodiment, the inter-gate distance S1 of the first opening region A1 is made wider than the inter-gate distance S2 of the second opening region A2, and the connection region 38 is selectively disposed in the first opening region A1. Therefore, compared to a case where the connection region 38 is also disposed in the second opening region A2, the area of the connection region 38 can be increased, so that the electrical resistance of the connection region 38 can be reduced. Thus, the voltage drop generated in the connection region 38 by the avalanche current can be suppressed, so that the potential of the electric field relaxation layer 50 can be stabilized. It becomes possible to suppress deterioration of the gate insulating film 20a.

The semiconductor device 1 of the present embodiment is provided with the SJ layer 60. The p-type impurity concentration of the electric field relaxation layer 50 is higher than the p-conductivity type impurity concentration of the second column 62 of the SJ layer 60 and the body region 34. By increasing the impurity concentration of the electric field relaxation layer 50, the electrical resistance of the electric field relaxation layer 50 can be reduced, so that the voltage drop generated in the electric field relaxation layer 50 can be suppressed. Further, by reducing the impurity concentrations of the second column 62, the depletion layer can be spread throughout the SJ layer 60, so that the breakdown voltage can be improved. It becomes possible to achieve both improvement in reliability of the gate insulating film 20a and improvement in breakdown voltage of the semiconductor device 1.

The connection region 38 is electrically connected to the plurality of base portions 50a along the y direction (see FIG. 4). Thus, the avalanche current flowing from the plurality of base portions 50a can be concentrated in the connection region 38 with the low electrical resistance and allowed to flow to the source electrode 14.

In the vertical top view, the first portion 50b of the electric field relaxation layer 50 overlaps with the connection region 38 (see FIG. 4). Thus, the electrical resistance can be reduced by increasing the contact area between the connection region 38 and the electric field relaxation layer 50. Since the voltage drop during the avalanche operation can be suppressed, the potential of the electric field relaxation layer 50 can be stabilized.

In the vertical top view, the second portion 50c of the electric field relaxation layer 50 overlaps with the gate portion 20 (see FIG. 4). Thus, since the electric field relaxation layer 50 can be disposed over the entire length in the y direction directly under the gate portion 20, the effect of relaxing the electric field in the gate insulating film 20a can be enhanced.

The electric field relaxation layer 50 includes the first electric field relaxation layer 51 (high concentration p-layer) and the second electric field relaxation layer 52 (low concentration p-layer) located below the first electric field relaxation layer 51. Thus, when a reverse bias is applied, the depletion layer can be spread inside the second electric field relaxation layer 52 with the lower impurity concentration, so that the breakdown voltage can be further improved. Further, the resistance of the discharge path of the avalanche current can be reduced by the first electric field relaxation layer 51 with the higher impurity concentration.

The lower end 38L of the connection region 38 is located below the lower end 51L of the first electric field relaxation layer 51. This allows a structure in which the connection region 38 (high concentration p-layer) penetrates into the second electric field relaxation layer 52 (low concentration p-layer). In the portion where the connection region 38 penetrates, the volume of the second electric field relaxation layer 52 with the lower impurity concentration decreases, so the depletion layer becomes difficult to spread. As a result, the breakdown voltage of the second electric field relaxation layer 52 can be locally lowered only at the portion where the connection region 38 penetrates. Thus, the generation location of holes due to avalanche can be limited to the portion where the connection region 38 penetrates. Since it is possible to suppress the avalanche current from being generated in the vicinity of the gate portion 20, deterioration of the gate insulating film 20a can be suppressed.

When the connection region 38 is formed with a high impurity concentration using ion implantation, the crystal defect density in the connection region 38 increases. Therefore, when an electric field is applied, a leakage current may occur in the connection region 38. Therefore, in the semiconductor device 1 of the present embodiment, the lower end 38L of the connection region 38 is located above the lower end 52L of the second electric field relaxation layer 52. By adopting a structure in which the lower end 38L of the connection region 38 is surrounded by the second electric field relaxation layer 52 with the lower impurity concentration, the electric field applied to the connection region 38 can be reduced. It becomes possible to suppress the generation of leakage current.

The upper end 62U of the second column 62 is separated from the lower end 51L of the first electric field relaxation layer 51 and the lower end 38L of the connection region 38. Thus, a structure can be achieved in which the second column 62 does not overlap with the first electric field relaxation layer 51 with the higher impurity concentration and the connection region 38 in the depth direction. It becomes possible to suppress a decrease in breakdown voltage due to disruption of the charge balance of the SJ layer 60.

In the vertical top view, the gate portion 20 and the connection region 38 are disposed apart from each other. Thus, the connection region 38, which is a current path for the avalanche current, can be separated from the gate insulating film 20a. It is possible to suppress the gate insulating film 20a from deteriorating due to local heat generation (temperature gradient) caused by the avalanche current.

The upper end 38U of the connection region 38 is in contact with the contact region 32. Thus, in the current path from the connection region 38 to the source electrode 14, the current does not pass through the body region 34 having low impurity concentration and high electrical resistance. The resistance of the discharge path of the avalanche current can be reduced.

During the avalanche operation, if the avalanche current flows laterally in the body region 34, a potential gradient is likely to be generated in the body region 34. As a result, there is a possibility that the semiconductor device 1 may malfunction. Therefore, in the semiconductor device 1 of the present embodiment, the connection region 38 is disposed within the range of the contact region 32 in the vertical top view. Thus, a structure in which the entire area of the upper end 38U of the connection region 38 is in contact with the contact region 32 can be realized. Therefore, the avalanche current passing through the connection region 38 can be made to flow upward toward the source electrode 14 at the shortest distance. It becomes possible to suppress the generation of a potential gradient in the body region 34.

### Modification of First Embodiment

In the first embodiment, the case where the arrangement ratio of the first inter-gate distance S1 and the second inter-gate distance S2 is “1:1” has been illustrated. However, the arrangement ratio is not limited to such an example. For example, as shown in FIG. 5, the arrangement ratio may be “1:2”. In FIG. 5, only the gate portions 20 and the connection regions 38 are shown, and illustration of other parts is omitted. Further, for example, the arrangement ratio may be “1:3”, “1:4”, or the like. As the arrangement ratio of the second inter-gate distance S2 is increased, the arrangement density of the gate portions 20 can be increased, so that the on-resistance of the semiconductor device 1 can be reduced.

The case where the arrangement ratio of the inter-gate distances S1 and S2 is the same throughout the entire chip of the semiconductor device 1 has been described, but the form is not limited to this. The arrangement ratio may be different between a chip inner region and a chip outer peripheral region in the vertical top view. For example, the arrangement ratio of the inter-gate distance S2 may be lower in the chip outer peripheral region than in the chip inner region. That is, the arrangement density of the connection regions 38 may be higher in the chip outer peripheral region than in the chip inner region. As the arrangement density of the connection regions 38 increases, the amount of heat generated when the avalanche current flows increases. Therefore, by arranging the region with a large amount of heat generation in the chip outer peripheral region where heat is less likely to be trapped and heat dissipation is higher, the heat resistance of the semiconductor device 1 can be improved.

### Second Embodiment

### Configuration of Semiconductor Device 201

In the first embodiment, the configuration in which the plurality of gate portions 20 extend in the y direction and are arranged in a stripe shape in the vertical top view has been illustrated. On the other hand, in the second embodiment, a configuration in which a plurality of gate portions 220 extend in the x and y directions and are arranged so as to have intersection portions will be illustrated. Also, in the second embodiment, a configuration in which the gate portion 220 is a planar type will be illustrated.

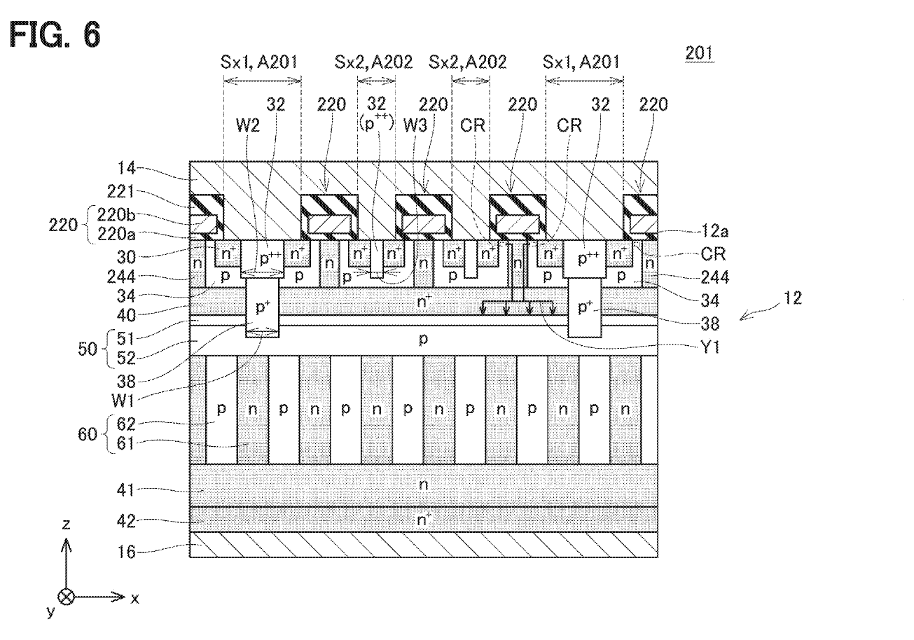

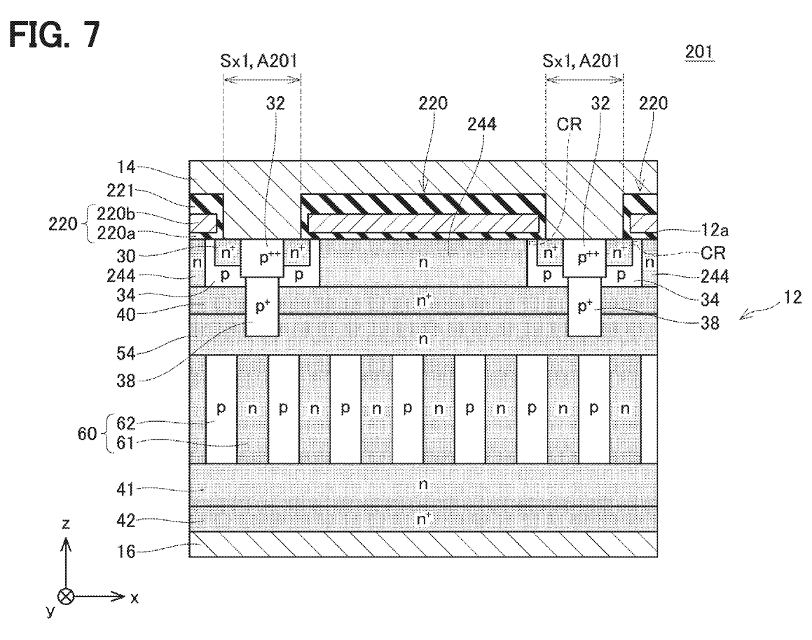

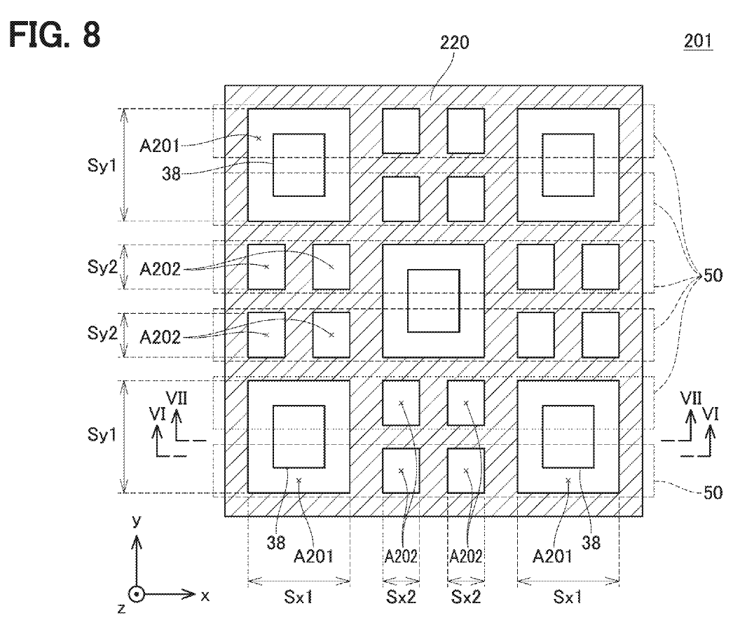

FIGS. 6 and 7 show cross-sectional views of main parts of a semiconductor device 201 according to the second embodiment. FIG. 8 shows a plan view of the semiconductor device 201 viewed from vertically above. In FIG. 8, the illustration of the source electrode 14 is omitted for ease of viewing. Also, the gate portion 220 is shown by hatching, and the electric field relaxation layer 50 is shown by dotted lines. FIG. 6 is a cross-sectional view taken along a line VI-VI in FIG. 8. FIG. 7 is a cross-sectional view taken along a line VII-VII in FIG. 8. That is, FIG. 6 is a cross-sectional view taken at a position passing through the electric field relaxation layer 50, and FIG. 7 is a cross-sectional view taken at a position passing through the n-type layer 54. Note that parts common to the semiconductor device 201 of the second embodiment and the semiconductor device 1 of the first embodiment are denoted by the same reference numerals, and description thereof is not repeated. Only contents specific to the semiconductor device 201 of the second embodiment will be described below.

The planar structure of the semiconductor device 201 will be described with reference to FIG. 8. The gate portions 220 extend in the y direction and the x direction. In other words, the gate portions 220 may include first extension portions extending in one of the x direction and the y direction and second extension portions extending the other of the x direction and the y direction. A plurality of rectangular opening regions are formed in regions surrounded by the gate portions 220. There are two types of opening regions: a first opening region A201 and a second opening region A202. The first opening region A201 has a side length Sx1 in the x direction and a side length Sy1 in the y direction. In the present embodiment, the side length Sx1 is smaller than the side length Sy1. The second opening region A202 has a side length Sx2 in the x direction and a side length Sy2 in the y direction. In the present embodiment, the side length Sx2 is smaller than the side length Sy2. The minimum side length (side length Sx2) of the second opening region A202 is smaller than the minimum side length (side length Sx1) of the first opening region A201.

The connection regions 38 are disposed in the regions corresponding to the plurality of first opening regions A201 and are not disposed in the regions corresponding to the plurality of second opening regions A202. That is, the connection regions 38 are arranged scattered in a dot pattern in the vertical top view.

The cross-sectional structure of the semiconductor device 201 will be described with reference to FIGS. 6 and 7. The semiconductor device 201 includes an n-type junction field effect transistor (JFET) region 244. The JFET region 244 is disposed in contact with the upper surface of the current spreading layer 40 and is exposed at the substrate surface 12a. An n-type impurity concentration of the current spreading layer 40 is higher than an n-type impurity concentration of the JFET region 244. The body region 34 is disposed adjacent to the JFET region 244. The source region 30 is separated from the current spreading layer 40 and the JFET region 244 by the body region 34. A channel region CR is formed in the body region 34 separating the JFET region 244 and the source region 30.

The gate portion 220 is a planar electrode portion. The gate portion 220 is disposed so as to face the JFET region 244 and the channel region CR. The gate portion 220 includes a gate insulating film 220a and a gate electrode 220b. The gate insulating film 220a is disposed on the substrate surface 12a. The gate electrode 220b is disposed on an upper surface of the gate insulating film 220a. An upper surface of the gate electrode 220b is covered with an interlayer insulating film 221. The gate electrode 220b is insulated from the source electrode 14 by the interlayer insulating film 221.

The contact regions 32 are disposed in both the region corresponding to the first opening region A201 and the region corresponding to the second opening region A202. Within the first opening region A201, the connection region 38 is disposed so as to be in contact with the lower end of the contact region 32. On the other hand, within the second opening region A202, the connection region 38 is not provided below the contact region 32. A width W3 of the contact region 32 in the second opening region A202 is smaller than a width W2 of the contact region 32 in the first opening region A201.

### Effects

Also in the semiconductor device 201 of the second embodiment, the similar effects to those of the semiconductor device 1 of the first embodiment can be achieved. That is, by selectively arranging the connection region 38 in the first opening region A201 having a large area, the area of the connection region 38 can be expanded, so that the electrical resistance can be reduced. Further, since the breakdown voltage can be maintained by the SJ layer 60, it is possible to increase the impurity concentration of the electric field relaxation layer 50, and the resistance of the electric field relaxation layer 50 can be reduced. Thus, the voltage drop generated in the electric field relaxation layer 50 by the avalanche current can be suppressed, so that the potential of the electric field relaxation layer 50 can be stabilized.

By extending the gate portion 220 in both the x and y directions, the arrangement density of the gate portion 220 can be increased compared to a case in which the gate portion 220 is extended only in one direction. Further, in the region where the connection region 38 is not disposed (second opening region A202), the arrangement density of the gate portion 220 can be increased by reducing the opening area. Therefore, since the arrangement density of the channel regions CR can be increased, the channel resistance of the semiconductor device 1 can be reduced.

By dispersedly arranging the connection regions 38 in a dot pattern, the area ratio of the region where the gate portion 220 can be disposed can be increased, and the gate portion 220 can be arranged uniformly. It becomes possible to reduce the channel resistance of the semiconductor device 1 and make the channel resistance uniform in the plane.

By adopting a structure in which the body region 34 and the electric field relaxation layer 50 are electrically connected via the connection region 38, the current spreading layer 40 can be disposed between the body region 34 and the electric field relaxation layer 50. Thus, as shown by an arrow Y1 in FIG. 6, electrons flowing from channel regions CR can be widely dispersed laterally with a small voltage drop via the low-resistance current spreading layer 40 and flow into the SJ layer 60. Therefore, the layout of the gate portion 220 and the pitch of the SJ layer 60 can be individually and optimally designed. It is possible to achieve both reduction in on-resistance and improvement in breakdown voltage.

### Modification of Second Embodiment

In the second embodiment, the case where two types of opening regions, the first opening region A201 and the second opening region A202, having different opening areas are provided has been illustrated. However, the configuration is not limited to such an example. Three or more types of opening regions having different opening areas may be provided. In this case, among the three or more types of opening regions, the opening region having the minimum side length corresponds to the second opening region A202. Therefore, the connection region 38 is not disposed in the opening region having the minimum side length. The minimum side length may be either the side length Sx or the side length Sy.

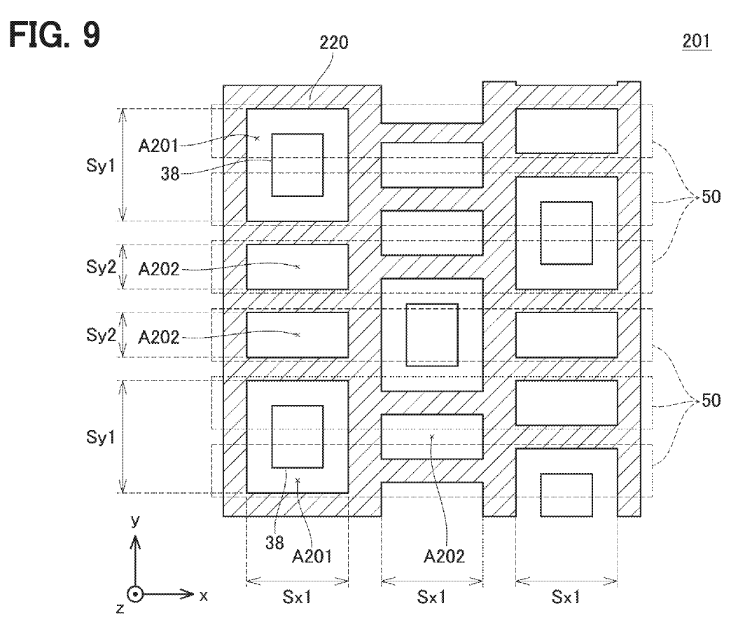

The mode in which the gate portion 220 extends in the x and y directions may vary. In FIG. 8 of the second embodiment, the mode in which the gate portions 220 extend linearly in both the x direction and the y direction and are arranged in a lattice shape has been illustrated, but the mode is not limited to this. As shown in an example of FIG. 9, a mode may be adopted in which the gate portions 220 extend linearly in the y direction and extend in a zigzag shape in the x direction, and are arranged in a ladder shape.

The gate portion 220 extending in the x and y directions described in the second embodiment is not limited to the planar type. The gate portion 220 may be the trench type illustrated in the first embodiment.

### Other Modifications

Modifications applicable to each of the embodiments described above will be described hereinafter.

In the above embodiment, the configuration in which the second column 62 extends in the y direction and the electric field relaxation layer 50 extends in the x direction has been illustrated. However, the present disclosure is not limited to such a configuration. The extending directions of the second column 62 and the electric field relaxation layer 50 may be any direction as long as they intersect each other in the vertical top view. For example, a configuration in which the second column 62 and the electric field relaxation layer 50 intersect at 45° may be adopted.

In the above embodiment, the configuration in which the electric field relaxation layer 50 extends in the x direction and the gate portion 20 extends in the y direction has been illustrated. However, the present disclosure is not limited to such a configuration. The extending directions of the electric field relaxation layer 50 and the gate portion 20 may be any direction as long as they intersect each other in the vertical top view. For example, a configuration in which the electric field relaxation layer 50 and the gate portion 20 intersect at 45° may be adopted.

In the above embodiment, the configuration in which the switching element is a MOSFET has been illustrated. However, the switching element is not limited to the MOSFET. For example, the semiconductor device may be provided with various switching element, such as an insulated gate bipolar transistor (IGBT). For example, a semiconductor device with the IGBT can be obtained by replacing the n-type drain layer 42 with a p-type collector layer in the MOSFET. In this case, the source and drain are rephrased as emitter and collector.

The configurations of the technology disclosed in this specification are listed below.

### Configuration1

A semiconductor device includes: a lower electrode; a semiconductor substrate disposed in contact with an upper surface of the lower electrode and including a source region and a body region; a plurality of gate portions each disposed to face the body region and the source region; and an upper electrode disposed above a substrate surface of the semiconductor substrate and electrically connected to the source region and the body region. The semiconductor substrate includes: a super junction layer disposed above the lower electrode and having a first column of a first conductivity type extending in a first direction and a second column of a second conductivity type extending in the first direction, the first column and the second column being alternately and repeatedly arranged along a second direction intersecting the first direction; a plurality of electric field relaxation layers of the second conductivity type disposed in contact with an upper surface of the super junction layer, extending in a third direction intersecting the first direction, and disposed so that a semiconductor layer of the first conductivity type is interposed between adjacent electric field relaxation layers; a current spreading layer of the first conductivity type disposed in contact with upper surfaces of the plurality of electric field relaxation layers; the body region of the second conductivity type disposed in contact with an upper surface of the current spreading layer; a connection region of the second conductivity type having an upper part in contact with the body region and a lower part in contact with at least one of the plurality of electric field relaxation layers, and electrically connecting the body region and the at least one of the plurality of electric field relaxation layers; and the source region of the first conductivity type disposed in an upper part of the body region and exposed at the substrate surface of the semiconductor substrate. The plurality of

electric field relaxation layers have a second conductivity type impurity concentration higher than a second conductivity type impurity concentration of the second column. In a vertical top view when viewed perpendicular to the substrate surface of the semiconductor substrate, the plurality of electric field relaxation layers partially overlap with the plurality of gate portions. In the vertical top view, the plurality of gate portions are disposed so that a plurality of first opening regions and a plurality of second opening regions are defined between adjacent gate portions, each of the plurality of first opening regions is defined between adjacent gate portions spaced apart at a first inter-gate distance, each of the plurality of second opening regions is defined between adjacent gate portions spaced apart at a second inter-gate distance smaller than the first inter-gate distance. The connection region is disposed in at least one of the plurality of first opening regions and is not disposed in the plurality of second opening regions.

### Configuration 2

In the semiconductor device as in the configuration 1, the connection region has a second conductivity type impurity concentration higher than a second conductivity type impurity concentration of the body region.

### Configuration 3

In the semiconductor device as in the configuration 1 or 2, each of the plurality of gate portions and each of the plurality of first opening regions continuously extend in a fourth direction intersecting the third direction. The connection region continuously extends in the fourth direction in the at least one of the plurality of first opening regions. The connection region is electrically connected to the plurality of electric field relaxation layers along the fourth direction.

### Configuration 4

In the semiconductor device as in the configuration 3, the plurality of electric field relaxation layers include a first portion continuously extending in the fourth direction. In the vertical top view, the first portion overlaps with the connection region.

### Configuration 5

In the semiconductor device as in the configuration 3 or 4, the plurality of electric field relaxation layers include a second portion continuously extending in the fourth direction. In the vertical top view, the second portion overlaps with at least one of the plurality of gate portions.

### Configuration 6

In the semiconductor device as in any one of the configurations 1 to 5, the plurality of electric field relaxation layers each include a first electric field relaxation layer and a second electric field relaxation layer located below the first electric field relaxation layer. A second conductivity type impurity concentration of the first electric field relaxation layer is higher than a second conductivity type impurity concentration of the second electric field relaxation layer.

### Configuration 7

In the semiconductor device as in the configuration 6, a lower end of the connection region is located below a lower end of the first electric field relaxation layer.

### Configuration 8

In the semiconductor device as in the configuration 6 or 7, the lower end of the connection region is located above a lower end of the second electric field relaxation layer.

### Configuration 9

In the semiconductor device as in any one of the configurations 6 to 8, an upper end of the second column is separated from a lower end of the first electric field relaxation layer and a lower end of the connection region.

### Configuration 10

In the semiconductor device as in any one of the configurations 1 to 3, the plurality of gate portions include first extension portions extending in a fourth direction intersecting the third direction and second extension portions extending in a fifth direction orthogonal to the fourth direction so as to define a plurality of opening regions

with a rectangular shape surrounded by the first extension portions and the second extension portions, in the vertical top view. The plurality of opening regions include at least one of the plurality of first opening regions and at least one of the plurality of second opening regions. The first inter-gate distance of the first opening region is defined by a minimum side length of the rectangular shape of one of the plurality of opening regions, and the second inter-gate distance of the second opening region is defined by a minimum side length of the rectangular shape of another one of the plurality of opening regions.

### Configuration 11

In the semiconductor device as in any one of the configurations of 1 to 10, the source region is separated from the current spreading layer by the body region. The semiconductor substrate has a trench extending from the substrate surface toward a deep portion so as to penetrate the source region and the body region and reach the current spreading layer. Each of the plurality of gate portions includes a gate electrode disposed in the trench through a gate insulating film, and the gate electrode faces the body region, which separates the current spreading layer and the source region, through the gate insulating film.

### Configuration 12

In the semiconductor device as in any one of the configurations 1 to 10, the plurality of gate portions each include a planar electrode portion disposed above the substrate surface through a gate insulating film. The semiconductor device further includes: a JFET region of the first conductivity type disposed in contact with the upper surface of the current spreading layer and disposed at a position exposed at the substrate surface. The body region is disposed adjacent to the JFET region. The source region is separated from the current spreading layer and the JFET region by the body region, and the plurality of gate portions are each disposed to face the JFET region and a portion of the body region separating the JFET region and the source region.

### Configuration 13

In the semiconductor device as in any one of the configurations 1 to 12, the plurality of gate portions are disposed apart from the connection region in the vertical top view.

### Configuration 14

In the semiconductor device as in any one of the configurations 1 to 13, in the semiconductor substrate, a contact region of the second conductivity type disposed at a position exposed at the substrate surface, adjacent to the source region, and in contact with the upper electrode. The contact region is in contact with an upper end of the connection region, and a second conductivity type impurity concentration of the contact region is higher than a second conductivity type impurity concentration of the connection region.

### Configuration 15

In the semiconductor device as in the configuration 14, in the vertical top view, the connection region is disposed within a region corresponding to the contact region.

According to the configuration 2, the electrical resistance of the connection region can be reduced. Thus, it is possible to suppress the voltage drop generated in the connection region by the avalanche current.

According to the configuration 3, the avalanche current flowing from the plurality of electric field relaxation layers can be concentrated in the low-resistance connection region.

According to the configuration 4, the electrical resistance can be reduced by increasing the contact area between the connection region and the electric field relaxation layer.

According to the configuration 5, the electric field relaxation layer can be disposed over the entire length of the gate portion directly under the gate portion. It becomes possible to enhance the effect of relaxing the electric field in the gate portion.

According to the configuration 6, since the depletion layer can be spread inside the second electric field relaxation layer with the lower impurity concentration, the breakdown voltage can be further improved. Further, the resistance of the discharge path of the avalanche current can be reduced by the first electric field relaxation layer with the higher impurity concentration.

According to the configuration 7, a structure in which the connection region penetrates into the second electric field relaxation layer can be achieved. The generation location of holes due to avalanche can be limited to the portion where the connection region penetrates.

According to the configuration 8, by adopting a structure in which the lower end of the connection region is surrounded by the second electric field relaxation layer, the electric field applied to the connection region can be reduced.

According to the configuration 9, a structure can be realized in which the second column does not overlap with the first electric field relaxation layer and the connection region in the depth direction. It becomes possible to suppress a decrease in breakdown voltage due to disruption of the charge balance of the super junction layer.

According to the configuration 10, by extending the gate portions in both the fourth direction and the fifth direction, the arrangement density of the gate portions can be increased compared to the case of extending it only in one direction.

According to the configuration 11, the semiconductor device can have the trench-type gate portions.

According to the configuration 12, the semiconductor device can have the planar-type gate portions.

According to the configuration 13, it is possible to suppress the gate portion from deteriorating due to local heat generation caused by the avalanche current.

According to the configuration 14, the resistance of the discharge path of the avalanche current can be reduced.

According to the configuration 15, it becomes possible to suppress the generation of a potential gradient in the body region.

Although the embodiments have been described in detail above, these are merely examples and do not limit the scope of claims. The technology described in the scope of claims includes various modifications and changes of the specific examples illustrated above. The technical elements described in this specification or the drawings exhibit technical usefulness alone or in various combinations, and are not limited to the combinations described in the claims at the time of filing. Further, the technology illustrated in this specification or the drawings achieves a plurality of objects simultaneously, and achieving one of the objects itself has technical usefulness.

What is claimed is:

1. A semiconductor device comprising:
a lower electrode;
a semiconductor substrate disposed in contact with an upper surface of the lower electrode and including a source region and a body region;
a plurality of gate portions each disposed to face the body region and the source region; and
an upper electrode disposed above a substrate surface of the semiconductor substrate and electrically connected to the source region and the body region, wherein
the semiconductor substrate includes:
a super junction layer disposed above the lower electrode and having a first column of a first conductivity type extending in a first direction and a second column of a second conductivity type extending in the first direction, the first column and the second column being alternately and repeatedly arranged along a second direction intersecting the first direction;
a plurality of electric field relaxation layers of the second conductivity type disposed in contact with an upper surface of the super junction layer, extending in a third direction intersecting the first direction, and disposed so that a semiconductor layer of the first conductivity type is interposed between adjacent electric field relaxation layers;
a current spreading layer of the first conductivity type disposed in contact with upper surfaces of the plurality of electric field relaxation layers;
the body region of the second conductivity type disposed in contact with an upper surface of the current spreading layer;
a connection region of the second conductivity type having an upper part in contact with the body region and a lower part in contact with at least one of the plurality of electric field relaxation layers, and electrically connecting the body region and the at least one of the plurality of electric field relaxation layers; and
the source region of the first conductivity type disposed in an upper part of the body region and exposed at the substrate surface of the semiconductor substrate,
the plurality of electric field relaxation layers have a second conductivity type impurity concentration higher than a second conductivity type impurity concentration of the second column,
in a vertical top view when viewed perpendicular to the substrate surface of the semiconductor substrate, the plurality of electric field relaxation layers partially overlap with the plurality of gate portions,
in the vertical top view, the plurality of gate portions are disposed so that a plurality of first opening regions and a plurality of second opening regions are defined between adjacent gate portions, each of the plurality of first opening regions is defined between adjacent gate portions spaced apart at a first inter-gate distance, each of the plurality of second opening regions is defined between adjacent gate portions spaced apart at a second inter-gate distance smaller than the first inter-gate distance, and
the connection region is disposed in at least one of the plurality of first opening regions and is not disposed in the plurality of second opening regions.

2. The semiconductor device according to claim 1, wherein
the connection region has a second conductivity type impurity concentration higher than a second conductivity type impurity concentration of the body region.

3. The semiconductor device according to claim 1, wherein
each of the plurality of gate portions and each of the plurality of first opening regions continuously extend in a fourth direction intersecting the third direction,
the connection region continuously extends in the fourth direction in the at least one of the plurality of first opening regions, and
the connection region is electrically connected to the plurality of electric field relaxation layers along the fourth direction.

4. The semiconductor device according to claim 3, wherein
the plurality of electric field relaxation layers include a first portion continuously extending in the fourth direction, and
in the vertical top view, the first portion overlaps with the connection region.

5. The semiconductor device according to claim 3, wherein
the plurality of electric field relaxation layers include a second portion continuously extending in the fourth direction, and
in the vertical top view, the second portion overlaps with at least one of the plurality of gate portions.

6. The semiconductor device according to claim 1, wherein
the plurality of electric field relaxation layers each include a first electric field relaxation layer and a second electric field relaxation layer located below the first electric field relaxation layer, and
the first electric field relaxation layer has a second conductivity type impurity concentration higher than a second conductivity type impurity concentration of the second electric field relaxation layer.

7. The semiconductor device according to claim 6, wherein
a lower end of the connection region is located below a lower end of the first electric field relaxation layer.

8. The semiconductor device according to claim 7, wherein
the lower end of the connection region is located above a lower end of the second electric field relaxation layer.

9. The semiconductor device according to claim 6, wherein
an upper end of the second column is separated from a lower end of the first electric field relaxation layer and a lower end of the connection region.

10. The semiconductor device according to claim 1, wherein
the plurality of gate portions include first extension portions extending in a fourth direction intersecting the third direction and second extension portions extending in a fifth direction orthogonal to the fourth direction so as to define a plurality of opening regions with a rectangular shape surrounded by the first extension portions and the second extension portions, in the vertical top view,
the plurality of opening regions include at least one of the plurality of first opening regions and at least one of the plurality of second opening regions, and
the first inter-gate distance of the first opening region is defined by a minimum side length of the rectangular shape of one of the plurality of opening regions, and the second inter-gate distance of the second opening region is defined by a minimum side length of the rectangular shape of another one of the plurality of opening regions.

11. The semiconductor device according to claim 1, wherein
the source region is separated from the current spreading layer by the body region,
the semiconductor substrate has a trench extending from the substrate surface toward a deep portion so as to penetrate the source region and the body region and reach the current spreading layer,
each of the plurality of gate portions includes a gate electrode disposed in the trench through a gate insulating film, and
the gate electrode faces the body region, which separates the current spreading layer and the source region, through the gate insulating film.

12. The semiconductor device according to claim 1, wherein
the plurality of gate portions each include a planar electrode portion disposed above the substrate surface through a gate insulating film,
the semiconductor device further comprising:
a junction field effect transistor (JFET) region of the first conductivity type disposed in contact with the upper surface of the current spreading layer and disposed at a position exposed at the substrate surface, wherein
the body region is disposed adjacent to the JFET region,
the source region is separated from the current spreading layer and the JFET region by the body region, and
the plurality of gate portions are each disposed to face the JFET region and a portion of the body region separating the JFET region and the source region.

13. The semiconductor device according to claim 1, wherein
in the vertical top view, the plurality of gate portions are disposed apart from the connection region.

14. The semiconductor device according to claim 1, further comprising:
a contact region of the second conductivity type disposed at a position exposed at the substrate surface, adjacent to the source region, and in contact with the upper electrode, wherein
the contact region is in contact with an upper end of the connection region, and
the contact region has a second conductivity type impurity concentration higher than a second conductivity type impurity concentration of the connection region.

15. The semiconductor device according to claim 14, wherein
in the vertical top view, the connection region is disposed within a region corresponding to the contact region.
